(19) United States
(12) Patent Application Publication
(10) Pub. No.: US 2015/0007890 A1
(43) Pub. Date: Jan. 8, 2015

(54) PHOTOVOLTAIC DEVICE COMPRISING HEAT RESISTANT BUFFER LAYER, AND METHOD OF MAKING THE SAME

(71) Applicant: TSMC Solar Ltd., Taichung City (TW)

(72) Inventors: Wei-Lun XU, Taipei City (TW); Ying-Chen CHAO, Hsinchu City (TW)

(21) Appl. No.: 13/936,376

(22) Filed: Jul. 8, 2013

(51) Int. Cl. H01L 31/0216; H01L 31/18

(52) U.S. Cl. CPC H01L 31/02167; H01L 31/18
USPC 136/260; 438/98

(57) ABSTRACT

A photovoltaic device includes a substrate, a back contact layer disposed above the substrate, an absorber layer comprising an absorber material disposed above the back contact layer, and a buffer layer disposed above the absorber layer. The buffer layer includes a first layer comprising the absorber material doped with zinc, and a second layer comprising a zinc-containing compound and a cadmium-containing compound.

### FIELD

The disclosure relates to photovoltaic devices generally, and more particularly relates to a photovoltaic device comprising a buffer layer, and the fabrication process of making the same.

### BACKGROUND

Photovoltaic devices (also referred to as solar cells) absorb sun light and convert light energy into electricity. Photovoltaic devices and manufacturing methods therefor are continually evolving to provide higher conversion efficiency with thinner designs.

Thin film solar cells are based on one or more layers of thin films of photovoltaic materials deposited on a substrate. The film thickness of the photovoltaic materials ranges from several nanometers to tens of micrometers. Examples of such photovoltaic materials include cadmium telluride (CdTe), copper indium gallium selenide (CIGS) and amorphous silicon (α-Si). These materials function as light absorbers. A photovoltaic device can further comprise other thin films such as a buffer layer, a back contact layer, and a front contact layer.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like reference numerals denote like features throughout specification and drawings.

FIGS. 1A-1F are cross-sectional views of a portion of an exemplary photovoltaic device during fabrication, in accordance with some embodiments.

FIG. 2 is a flow chart diagram illustrating a method of fabricating an exemplary photovoltaic device in accordance with some embodiments.

FIG. 3 is a flow chart diagram illustrating a method of forming a second layer of a buffer layer during fabricating an exemplary photovoltaic device in accordance with some embodiments.

FIGS. 4A and 4B are cross-sectional views of a portion of a photovoltaic device illustrating an exemplary buffer layer having a zinc-containing compound of different shapes in the second layer of a buffer layer in accordance with some embodiments.

FIGS. 5A-5C are cross-sectional views of a portion of an exemplary photovoltaic device having a zinc-containing compound and a cadmium-containing compound in the second layer of the buffer layer in accordance with some embodiments.

FIG. 6 is a flow chart diagram illustrating a method of fabricating an exemplary photovoltaic device of FIG. 5C in accordance with some embodiments.

FIGS. 7A-7D are cross-sectional views of a portion of an exemplary photovoltaic device having a buffer layer having a three-layer structure in accordance with some embodiments.

FIG. 8 is a flow chart diagram illustrating a method of fabricating an exemplary photovoltaic device of FIG. 7D in accordance with some embodiments.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Crystalline multinary-metal chalcogenide composition are of particular interest in development of photovoltaic devices. Thin-film photovoltaic devices typically use semiconductors such as CdTe or copper indium gallium sulfide/selenide (CIGS) as an absorber material for photon absorption. Due to toxicity of cadmium and the limited availability of indium, alternatives such as copper tin sulfide (Cu₂SnS₃ or “CTS”) and copper zinc tin sulfide (Cu₂ZnSnS₄ or “CZTS”) can be also used. Based on structure, some of these materials are of chalcopyrite family (e.g., GIGS) or kesterite family (e.g., BZnSnS and CZTS).

In a thin-film photovoltaic device, a buffer layer comprising a suitable material such as a single layer of CdS is disposed above an absorber layer in some embodiments to provide at least two functions. First, the buffer layer and the absorber layer, which both comprises a semiconductor material, provide a p-n or n-p junction. Second, a photovoltaic device generally comprises a front- and a back-contact, which are made of a conductive material. If the front- and the back contact layers are unintentionally connected because of defects in the think films, an unwanted short circuit (shunt path) will be provided. Such phenomenon decreases performance of the photovoltaic devices, and can cause the devices to fail to operate within specifications. The absorber layer can prevent such short circuiting, which could otherwise occur.

However, these dual functions could not be easily and separately controlled through using a buffer having one-layer structure in some embodiments. Meanwhile, a long term degradation and heat degradation in device performance occurs in a photovoltaic device comprising CdS due to diffusion of Cd. Recombination of charge carriers is another major factor in determining the losses in the conversion efficiency of photovoltaic devices.

This disclosure provides a photovoltaic device and the method for making the same. In accordance with some embodiments, a photovoltaic device comprises a substrate, a back contact layer disposed above the substrate, an absorber layer comprising an absorber material disposed above the back contact layer, and a buffer layer disposed above the absorber layer. The buffer layer includes at least two layers. In some embodiments, the buffer layer comprises a first layer comprising the absorber material doped with zinc, and a second layer comprising a zinc-containing compound and a cadmium-containing compound. In some embodiments, the photovoltaic device further comprises a transparent conductive layer disposed over the buffer layer. The buffer layer having at least two layers provides improved heat resistance and reduced recombination. Thus, the resulting photovoltaic device has excellent photovoltaic efficiency. The disclosure method and device are applicable to any photovoltaic device comprising a crystalline multinary-metal chalcogenide composition, particularly a material of a chalcopyrite family or a kesterite family.

Unless expressly indicated otherwise, references to “GIGS” made in this disclosure will be understood to encompass a material comprising copper indium gallium sulfide and/or selenide, for example, copper indium gallium selenide, copper indium gallium sulfide, and copper indium gallium sulfide/selenide. A selenide material may comprise sulfide or selenide can be completely replaced with sulfide. Similarly, references to “chalcopyrite family” or “chalcopyrite like” materials are understood to encompass a family or class of material having a chalcopyrite type of structure (e.g., GIGS). References to “kesterite family” or “kesterite like” materials are understood to encompass a family or class of material having a kesterite type of structure (e.g., BZnSnS and CZTS).

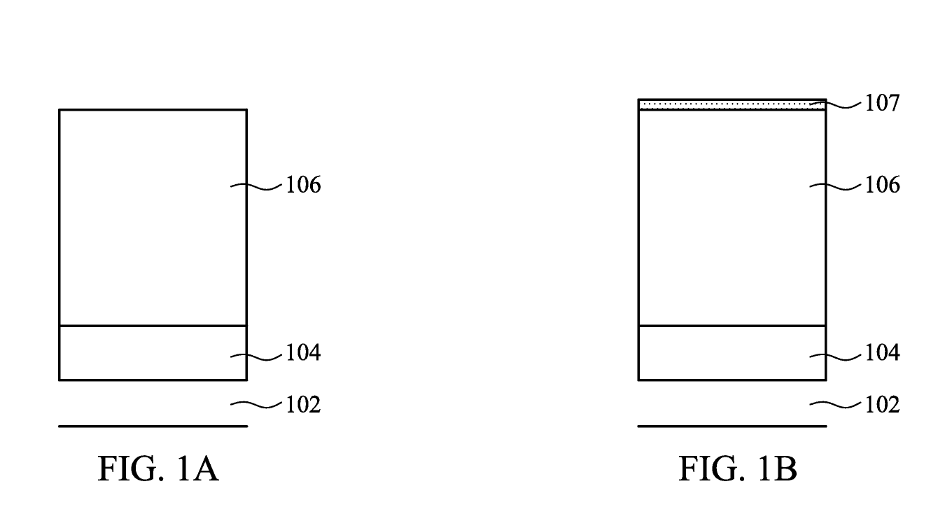

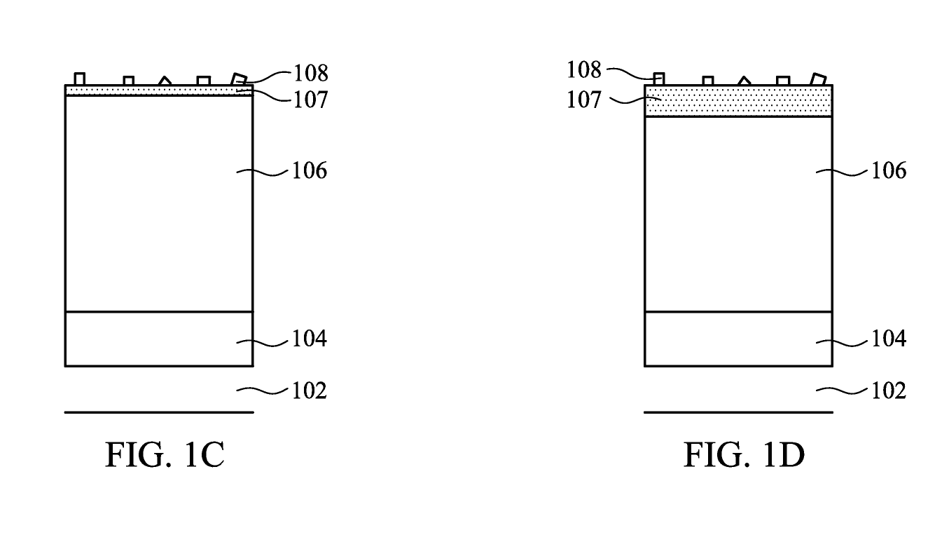

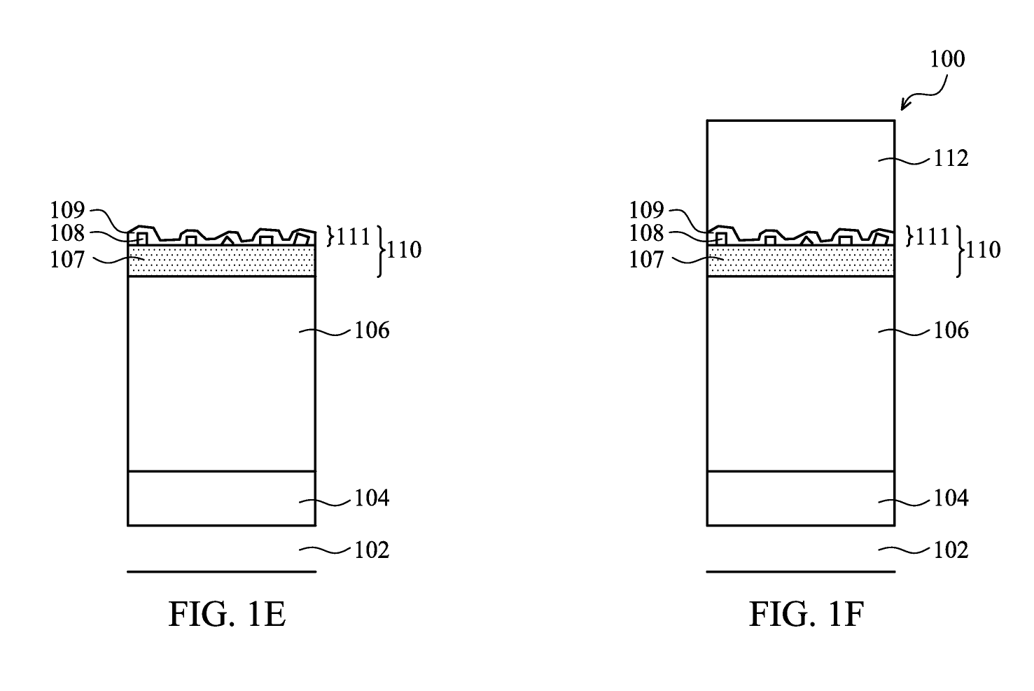

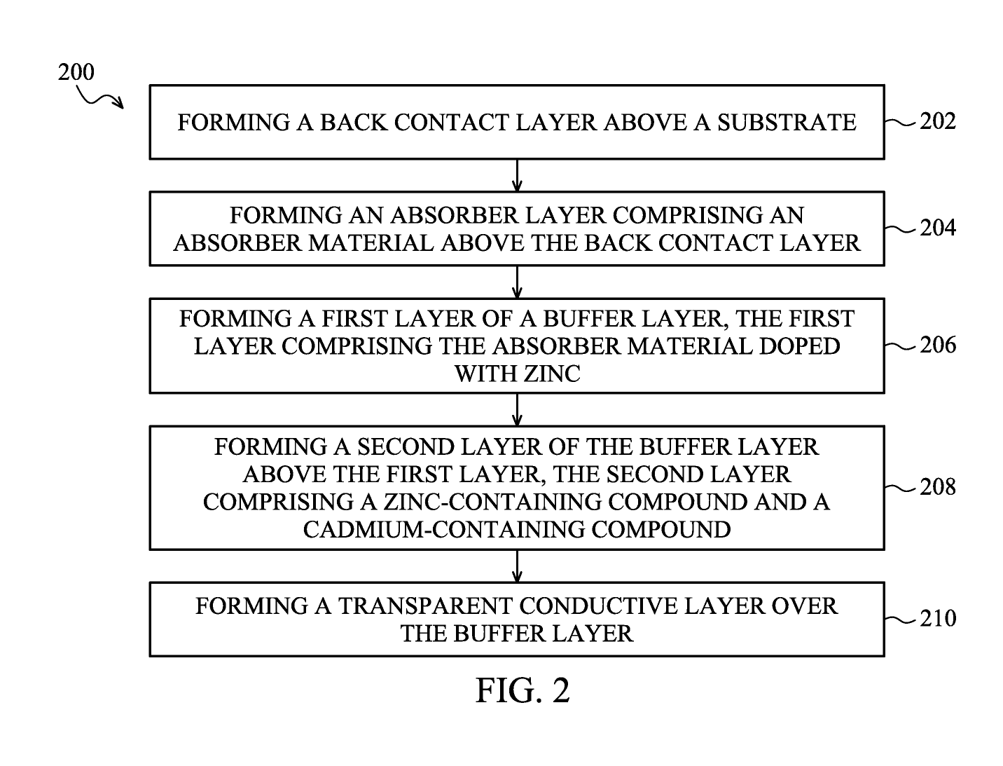

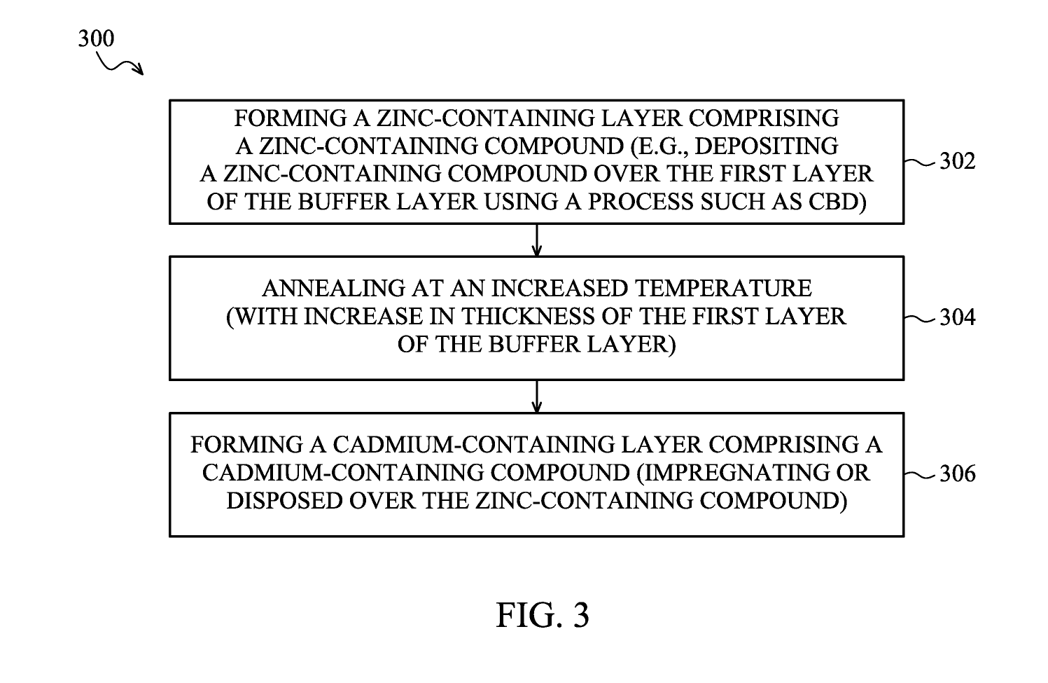

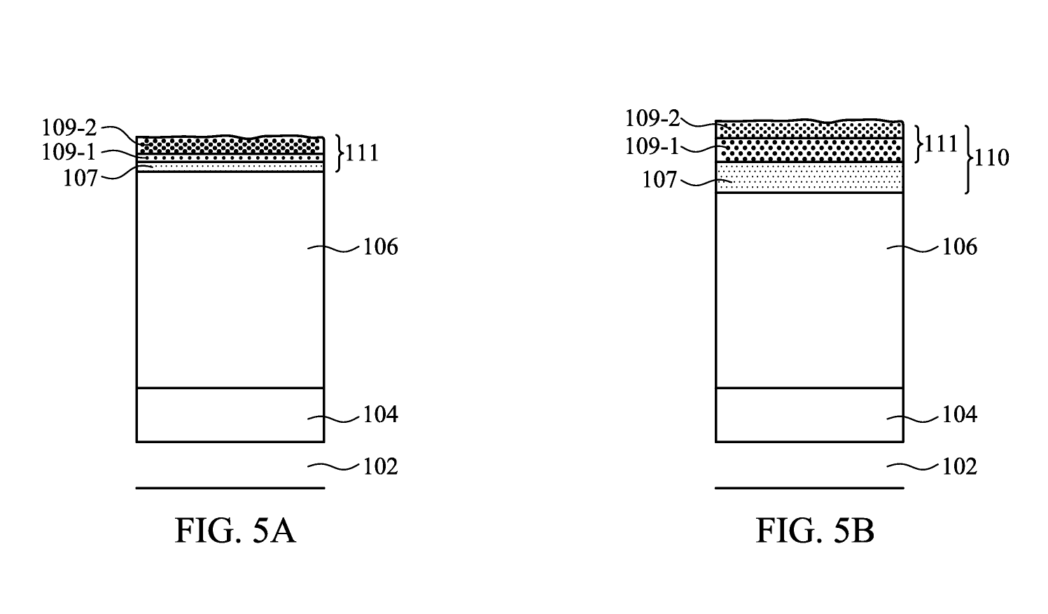

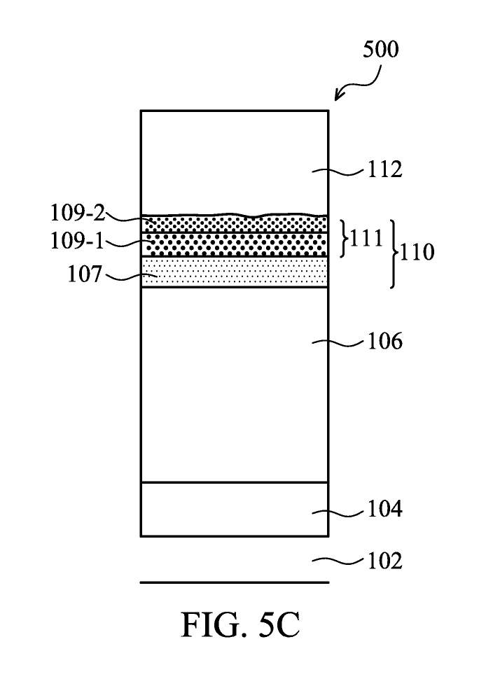

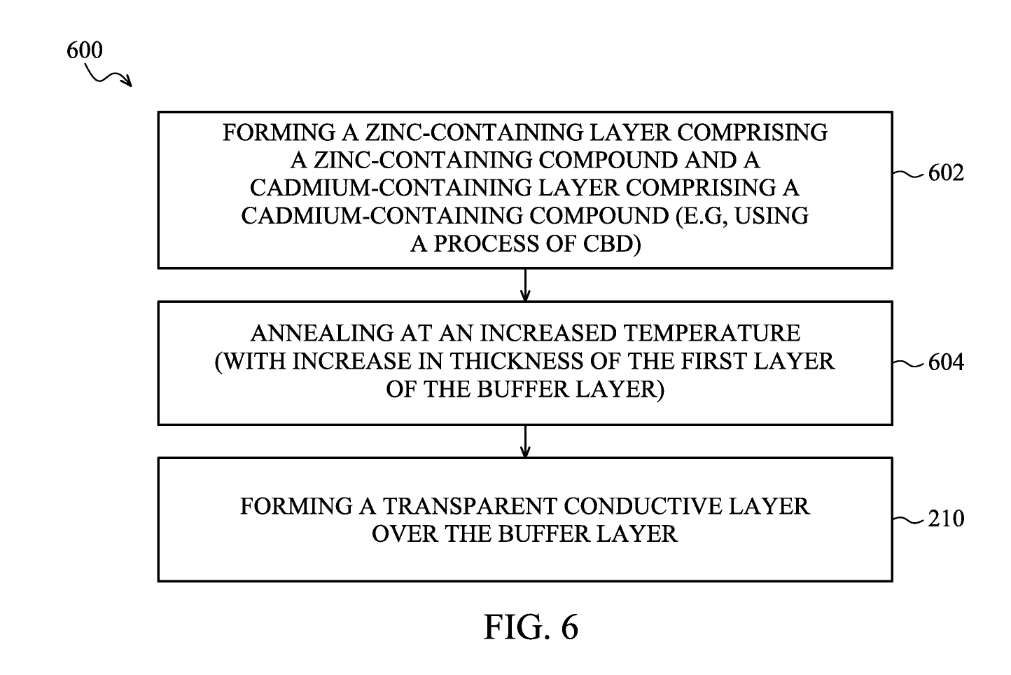

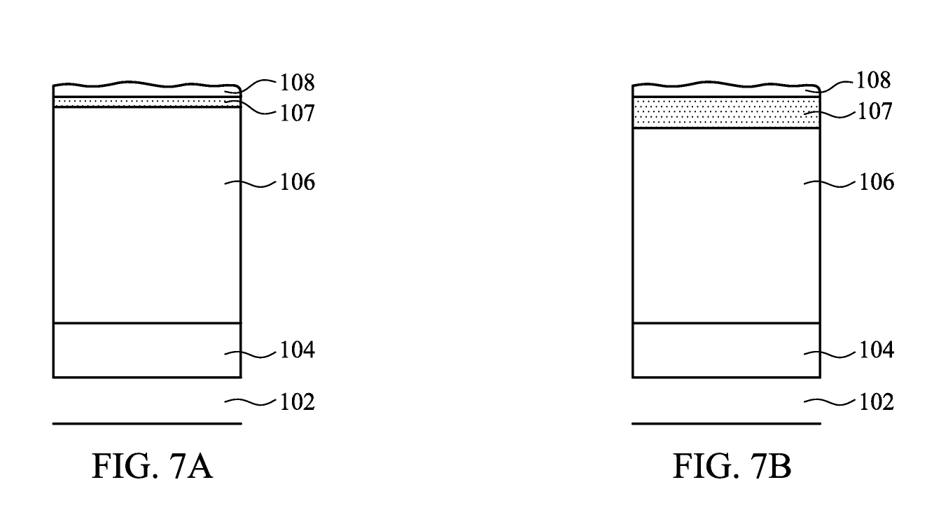

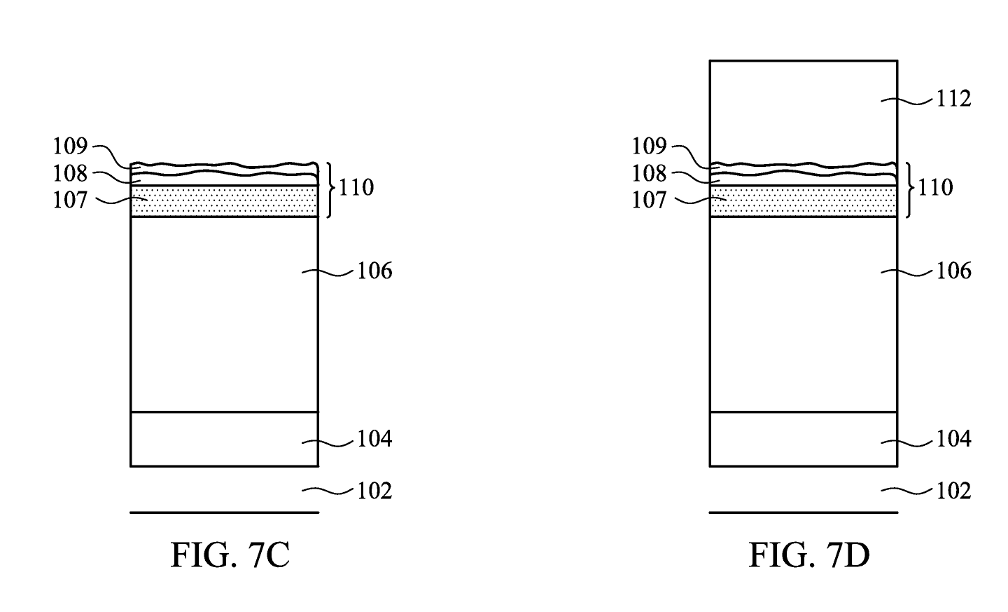

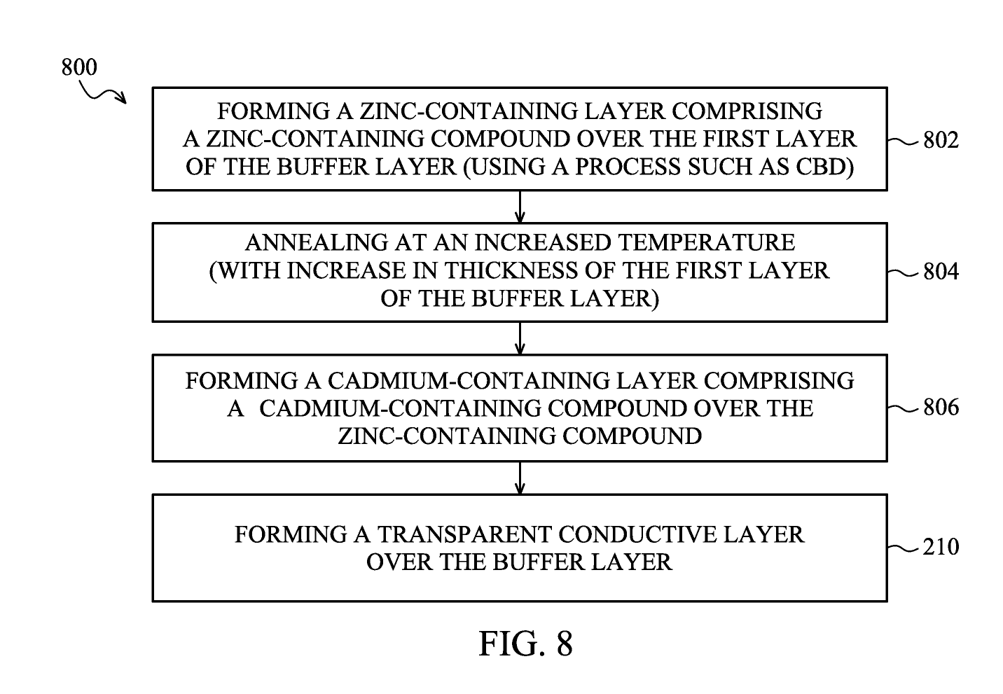

In FIGS. 1A-1D, 4A-4B, 5A-5C and 7A-7D, like items are indicated by like reference numerals, and for brevity, descriptions of the structure, provided above with reference to the previous figures, are not repeated. The methods described in FIGS. 2 and 3 are described with reference to the exemplary structures described in FIGS. 1A-1D. The methods described in FIGS. 6, and 8 are described with reference to the exemplary structures described in FIGS. 5A-5C and 7A-7D, respectively.

FIG. 2 is a flow chart diagram illustrating a method 200 of fabricating an exemplary photovoltaic device 100 in accordance with some embodiments. FIGS. 1A-1F are cross-sectional views of a portion of an exemplary photovoltaic device 100 during fabrication, in accordance with some embodiments.

At step 202, a back contact layer 104 is formed above a substrate 102. At step 204, an absorber layer 106 comprising an absorber material is formed above the back contact layer 104. The resulting structure of a portion of a photovoltaic device 100 is illustrated in FIG. 1A.

Substrate 102 and back contact layer 104 are made of any material suitable for thin film photovoltaic devices. Examples of materials suitable for use in substrate 102 include but are not limited to glass (such as soda lime glass), polymer (e.g., polyimide) film and metal foils (such as stainless steel). The film thickness of substrate 102 is in any suitable range, for example, in the range of 0.1 mm to 5 mm in some embodiments.

Examples of suitable materials for back contact layer 104 include, but are not limited to copper, nickel, molybdenum (Mo), or any other metals or conductive material. Back contact layer 104 can be selected based on the type of thin film photovoltaic device. For example, in a CIGS thin film photovoltaic device, back contact layer 104 is Mo in some embodiments. In a CdTe thin film photovoltaic device, back contact layer 104 is copper or nickel in some embodiments. The thickness of back contact layer 104 is on the order of nanometers or micrometers, for example, in the range from 100 nm to 20 microns. The thickness of back contact layer 104 is in the range of from 200 nm to 10 microns in some embodiments. Back contact layer 104 can be also etched to form a pattern.

An absorber layer 106 for photon absorption is formed above back contact layer 104. Absorber layer 106 is a p-type or n-type semiconductor material. Examples of materials suitable for absorber layer 106 include but are not limited to cadmium telluride (CdTe), copper indium gallium selenide (CIGS), amorphous silicon (α-Si). Absorber layer 106 can comprise material of a chalcopyrite family (e.g., GIGS) or kesterite family (e.g., BZnSnS and CZTS). In some embodiments, absorber layer 106 is a semiconductor comprising copper, indium, gallium and selenium, such as CuInₓGa₍₁₋ₓ₎Se₂, where x is in the range of from 0 to 1. In some embodiments, absorber layer 106 is a p-type semiconductor comprising copper, indium, gallium and selenium. Absorber layer 106 has a thickness on the order of nanometers or micrometers, for example, 0.5 microns to 10 microns. In some embodiments, the thickness of absorber layer 106 is in the range of 500 nm to 2 microns.

Absorber layer 106 can be formed according to methods such as sputtering, chemical vapor deposition, printing, electrodeposition or the like. For example, CIGS is formed by first sputtering a metal film comprising copper, indium and gallium at a specific ratio, followed by a selenization process of introducing selenium or selenium containing chemicals in gas state into the metal firm. In some embodiments, the selenium is deposited by evaporation physical vapor deposition (PVD).

At step 206, a first layer 107 of a buffer layer 110 is formed. The first layer 107 comprises the absorber material doped with zinc. The resulting structure of a portion of the photovoltaic device 100 during fabrication after step 206 is illustrated in FIG. 1B. In some embodiments, the first layer 107 is directly formed as a separate layer over the absorber layer 106. In some embodiments, the first layer 107 of the buffer layer 110 is formed through doping zinc such as zinc ion into a top surface of the absorber layer 106. For example, the first layer 107 of buffer layer 110 comprises copper indium gallium selenide (GIGS) doped with zinc in the range of from 0.1 atomic % to 5 atomic %. Copper indium gallium selenide (GIGS) in the absorber layer 106 can further comprise a small of amount of copper indium gallium sulfide. In some embodiments, copper indium gallium sulfide can be the absorber material. The first layer 107 of buffer layer 110 is zinc doped copper indium gallium sulfide. In some embodiments, the absorber layer 106 is made of a p-type semiconductor and comprises GIGS. The first layer 107 is zinc doped GIGS, which is an n-type semiconductor. In some embodiments, the first layer 107 of buffer layer 110 is further doped with cadmium. The first layer 107 of buffer layer 110 can have a thickness in the range of from 1 nm to 100 nm, for example, from 5 nm to 20 nm.

At step 208 of FIG. 2, a second layer 111 of buffer layer 110 is formed above the first layer 107. The resulting structure of photovoltaic device 100 after step 208 is illustrated in FIG. 1B. The second layer 111 of buffer layer 110 comprises a zinc-containing compound and a cadmium-containing compound. The second layer 111 of buffer layer 110 can have different structures and can be formed in different approaches. FIG. 3 is a flow chart diagram illustrating one exemplary method of forming the second layer 111 of buffer layer 110 in accordance with some embodiments.

At step 302 of FIG. 3, a zinc-containing layer 108 comprising a zinc-containing compound is formed. The resulting structure is illustrated in FIG. 1C. In some embodiments, the step of forming the zinc-containing layer 108 comprises depositing a zinc-containing compound over the first layer 107 of buffer layer 110. Formation of zinc-containing layer 108 is achieved through a suitable process such as sputtering, chemical vapor deposition, or chemical bath deposition (CBD). Examples of a zinc-containing compound include but are not limited to ZnS, ZnO, Zn(OH)2, ZnSe, ZnS(O, OH), and ZnSe (O, OH), and combinations thereof. A mixture of ZnS, ZnO and Zn(OH)2, and a mixture of ZnSe, ZnO and ZnOH can be also used. In some embodiments, these materials can deposited through a hydrothermal reaction or chemical bath deposition (CBD) in a solution. Suitable chemicals for such a CBD deposition include but are not limited to ZnSO₄, ammonia and thiourea. For example, ZnO can be prepared through a hydrothermal reaction or chemical bath deposition in a solution. The solution comprises a zinc-containing salt and an alkaline chemical. Any zinc containing salt can be zinc nitrate, zinc acetate, zinc chloride, zinc sulfate, combinations and hydrates thereof. One example of hydrate is zinc nitrate hexahydrate, zinc nitrate or zinc acetate. The alkaline chemical in the solution can be a strong base such as KOH or NaOH or a weak base such as ammonia or an amine.

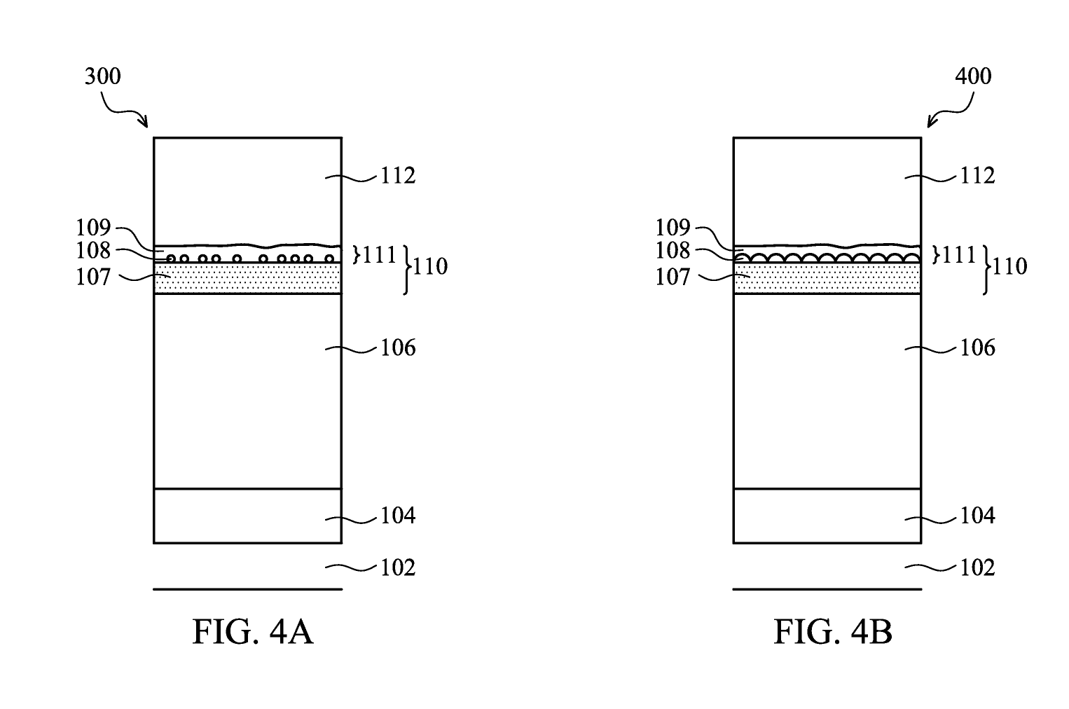

Such a zinc-containing compound in the second layer 111 of buffer layer 110 can be in any shape, for example, in a shape of selected from a group consisting of irregular particles, tubes, cubes and spherical particles. Zinc-containing compound in irregular particles or tubes are illustrated in FIGS. 1C-1F. Zinc-containing compound in spherical particles or beads in exemplary photovoltaic devices 300 and 400 are illustrated in FIGS. 4A and 4B, respectively. The zinc-containing layer 108 can be in a separate layer in some embodiments.

At step 304, annealing process can be optionally used in some embodiments. The resulting structure is illustrated in FIG. 1D. Annealing can be performed at an increased temperature. During the annealing process, zinc ions from the zinc-containing layer 108 can diffuse into the absorber layer 106. This process can result in an increase in thickness of the first layer 107 of buffer layer 110.

At step 306, a cadmium (Cd)-containing layer 109 comprising a cadmium-containing compound is formed. The resulting structure is illustrated in FIG. 1E. In some embodiments, the step of forming the Cd-containing layer 109 comprises depositing a Cd-containing compound over the zinc-containing layer 108. Formation of the Cd-containing layer 109 is achieved through a suitable process such as sputtering, chemical vapor deposition, or chemical bath deposition (CBD). In some embodiments, CdS, CdO, CdOH, CdS(O,OH), or a mixture of CdS, CdO and CdOH can deposited through a hydrothermal reaction or chemical bath deposition (CBD) in a solution. Suitable chemicals for such a CBD deposition include but are not limited to a suitable Cd-containing salt, and an alkaline chemical such as ammonia and thiourea. In some embodiments, either or both of the zinc-containing layer 108 and the cadmium-containing layer 109 are formed using a chemical bath deposition (CBD) method.

In some embodiments, as shown in FIG. 1E, the cadmium-containing compound in cadmium-containing layer 109 can impregnate or be disposed over the zinc-containing compound in the zinc-containing layer 108. In some embodiments, the second layer 111 of buffer layer 110 comprising and zinc-containing layer 108 and cadmium-containing layer 109 can be considered in a single-layer structure. In some embodiments, the zinc-containing layer 108 and the cadmium-containing layer 109 are two distinct layers in the second layer of the buffer layer. The thickness of the second layer 111 of the buffer layer 110 having a single-layer structure can be in the range from 1 nm to 200 nm, for example, from 5 nm to 80 nm.

Referring back to FIG. 2, at step 210, a transparent conductive layer 112 is formed over buffer layer 110. The resulting structure of a portion of the photovoltaic device 100 during fabrication after step 210 is illustrated in FIG. 1F.

Transparent conductive layer 112 is used in a photovoltaic (PV) device with dual functions: transmitting light to an absorber layer while also serving as a front contact to transport photo-generated electrical charges away to form output current. Transparent conductive oxides (TCOs) are used as front contacts in some embodiments. Both high electrical conductivity and high optical transmittance of the transparent conductive layer having TCO are desirable to improve photovoltaic efficiency.

Examples of a suitable material for transparent conductive layer 112 include but are not limited to transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron doped ZnO (BZO), and any combination thereof. A suitable material for transparent conductive layer 112 can also be a composite material comprising at least one of the transparent conductive oxide (TCO) and another conductive material, which does not significantly decrease electrical conductivity or optical transparency of transparent conductive layer 112. The thickness of transparent conductive layer 112 is in the order of nanometers or microns, for example in the range of from 0.3 nm to 2.5 μm in some embodiments.

FIG. 6 illustrates another exemplary method 600 of fabricating an exemplary photovoltaic device 500 comprising forming a second layer 111 of buffer layer 110 in accordance with some embodiments. The device structures are illustrated in FIGS. 5A-5C.

At step 602, a second layer 109 (109-1 and 109-2) of buffer layer 110 is formed over the first layer 107. Layer 109-1 is optional and may comprise a zinc-containing compound only. Layer 109-2 comprises a zinc-containing compound and a cadmium-containing compound, which are simultaneously formed, by a process (e.g., a CBD process) comprising steps 302 and 306 as described above.

At step 604, an annealing process, which is the same as step 304 as described is optionally used. During the annealing process, zinc ions from layers 109-1 and 109-2 can diffuse into the absorber layer 106 to give an increase in thickness of the first layer 107 of buffer layer 110. Both zinc ions and cadmium ions from layers 109-1 and 109-2 can also diffuse into the absorber layer 106 to a thicker layer 109-1 comprising an absorber material from the absorber layer 106 doped with both zinc and cadmium.

After step 604, step 210 as described can be used to form a transparent conductive layer 112 over buffer layer 110. The resulting structure of photovoltaic device 500 is illustrated in FIG. 5C.

FIG. 8 illustrates another exemplary method 800 of fabricating an exemplary photovoltaic device 700 of FIG. 7D in accordance with some embodiments. Method 800 is similar to method 200, except that the resulting buffer layer 110 has a three-layer structure.

In method 800, steps 802, 804 and 806 are the same as steps 302, 304 and 306, respectively. At step 802, as described in step 302 in FIG. 3, a zinc-containing layer 108 comprising a zinc-containing compound is formed over the first layer 107 of buffer layer 110. The resulting structure is illustrated in FIG. 7A. At step 804, as described in step 304 in FIG. 3, annealing process can be optionally used in some embodiments to result an increase in thickness of the first layer 107 of buffer layer 110. The resulting structure is illustrated in FIG. 7B. At step 806, as described at step 306 in FIG. 3, a cadmium (Cd)-containing layer 109 comprising a cadmium-containing compound is formed. The resulting structure is illustrated in FIG. 7C.

After step 806, in some embodiments, the buffer layer 110 has a three-layer structure, including the first layer 107 and the second layer 111. In some embodiments, the first layer 107 of buffer layer 110 comprises copper indium gallium selenide (GIGS) doped with zinc in the range of from 0.1 atomic % to 5 atomic %. The first layer 107 of buffer layer 110 can have the thickness in the range of from 5 nm to 20 nm. The second layer 111 of the buffer layer 110 has a two-layer structure, including zinc-containing layer 108 comprising the zinc-containing compound, and cadmium-containing layer 109 comprising the cadmium-containing compound. Zinc-containing layer 108 can has a thickness in the range of from 1 nm to 60 nm (e.g., from 5 nm to 20 nm), and cadmium-containing layer has a thickness in the range of 1 nm to 100 nm (e.g., from 5 nm to 60 nm) in some embodiments. In another word, buffer layer 110 includes the first layer 107 comprising the absorber material doped with zinc, a second layer 108 comprising a zinc-containing compound, and a third layer 109 comprising a cadmium-containing compound.

In some other embodiments, the second layer 108 comprises at least one of zinc sulfide and zinc selenide, and has a thickness in the range of from 5 nm to 20 nm, and the third layer 109 comprises cadmium sulfide and has a thickness in the range of from 5 nm to 60 nm.

After step 810, step 210 as described can be used to form a transparent conductive layer 112 over buffer layer 110. The resulting structure of photovoltaic device 700 is illustrated in FIG. 7D.

As described above, in one aspect, the present disclosure provides a photovoltaic device. Examples of a photovoltaic device include but are not limited to the exemplary device 100, 300, 400, 500 and 700, as described in FIGS. 1F, 4A, 4B, 5C and 7D, respectively. The exemplary device may further comprise other parts such as scribe lines.

The present disclosure provides a photovoltaic device and a method of fabricating such a photovoltaic device. In accordance with some embodiments, a photovoltaic device comprises a substrate, a back contact layer disposed above the substrate, an absorber layer comprising an absorber material disposed above the back contact layer, and a buffer layer disposed above the absorber layer. The buffer layer includes a first layer comprising the absorber material doped with zinc, and a second layer comprising a zinc-containing compound and a cadmium-containing compound. In some embodiments, the photovoltaic device further comprises a transparent conductive layer disposed over the buffer layer.

In some embodiments, the first layer of the buffer layer comprises copper indium gallium selenide (GIGS) doped with zinc in the range of from 0.1 atomic % to 5 atomic %. The first layer of the buffer layer has a thickness in the range of from 1 nm to 100 nm, for example, from 5 nm to 20 nm. In some embodiments, the first layer of the buffer layer is further doped with cadmium. In some embodiments, the second layer of the buffer layer has a two-layer structure, including a zinc-containing layer comprising the zinc-containing compound, and a cadmium-containing layer comprising the cadmium-containing compound. The zinc-containing layer can has a thickness in the range of from 1 nm to 60 nm (e.g., from 5 nm to 20 nm), and the cadmium-containing layer has a thickness in the range of 1 nm to 100 nm (e.g., from 5 nm to 60 nm) in some embodiments. In some other embodiments, the second layer of the buffer layer has a single-layer structure and comprises the zinc-containing compound disposed over the first layer of the buffer layer, and the cadmium-containing compound impregnating the zinc-containing compound. The zinc-containing compound in the second layer of the buffer layer can be in a shape of selected from a group consisting of irregular particles, tubes, and spherical particles. The thickness of the second layer of the buffer layer having a single-layer structure can be in the range from 1 nm to 200 nm, for example, from 5 nm to 80 nm.

Some embodiments also provide a photovoltaic device comprising a substrate, a back contact layer disposed above the substrate, an absorber layer comprising an absorber material disposed above the back contact layer, and a buffer layer disposed above the absorber layer. The buffer layer includes a first layer comprising the absorber material doped with zinc, a second layer comprising a zinc-containing compound, and a third layer comprising a cadmium-containing compound. In some embodiments, the first layer of the buffer layer comprises copper indium gallium selenide (GIGS) doped with zinc in the range of from 0.1 atomic % to 5 atomic %. The first layer of the buffer layer can have the thickness in the range of from 5 nm to 20 nm. In some embodiments, the second layer comprises at least one of zinc sulfide and zinc selenide, and has a thickness in the range of from 5 nm to 20 nm, and the third layer comprises cadmium sulfide and has a thickness in the range of from 5 nm to 60 nm.

In another aspect, the present disclosure also provides a method of fabricating a photovoltaic device. The method comprises forming a back contact layer above a substrate, forming an absorber layer comprising an absorber material above the back contact layer, forming a first layer of a buffer layer, the first layer comprising the absorber material doped with zinc, and forming a second layer of the buffer layer above the first layer. The second layer comprises a zinc-containing compound and a cadmium-containing compound. In some embodiments, the method further comprises forming a transparent conductive layer over the buffer layer.

In some embodiments, the first layer of the buffer layer is formed through doping zinc into a top surface of the absorber layer. In some embodiments, the step of forming the second layer of the buffer layer comprises forming a zinc-containing layer comprising a zinc-containing compound, and forming a cadmium-containing layer comprising a cadmium-containing compound. In some embodiments, the step of forming the second layer of the buffer layer comprises depositing a zinc-containing compound over the first layer of the buffer layer, and forming a cadmium-containing compound impregnating or disposed over the zinc-containing compound, in some embodiments, the second layer of the buffer layer has a single-layer structure. The zinc-containing compound in the second layer of the buffer layer can be in a shape of selected from a group consisting of irregular particles, tubes, and spherical particles. In some embodiments, the zinc-containing layer and the cadmium-containing layer are two distinct layers in the second layer of the buffer layer. In some embodiments, either or both of the zinc-containing layer and the cadmium-containing layer are formed using a chemical bath deposition (CBD) method.

Although the subject matter has been described in terms of exemplary embodiments, it is not limited thereto. Rather, the appended claims should be construed broadly, to include other variants and embodiments, which may be made by those skilled in the art.

What is claimed is:

1. A photovoltaic device comprising
a substrate;
a back contact layer disposed above the substrate;
an absorber layer comprising an absorber material disposed above the back contact layer; and
a buffer layer disposed above the absorber layer,
wherein the buffer layer includes a first layer comprising the absorber material doped with zinc, and a second layer comprising a zinc-containing compound and a cadmium-containing compound.

2. The photovoltaic device of claim 1, further comprising
a transparent conductive layer disposed over the buffer layer.

3. The photovoltaic device of claim 1, wherein the first layer of the buffer layer comprises copper indium gallium selenide (GIGS) doped with zinc in the range of from 0.1 atomic % to 5 atomic %.

4. The photovoltaic device of claim 1, wherein the first layer of the buffer layer has a thickness in the range of from 1 nm to 100 nm.

5. The photovoltaic device of claim 1, wherein the first layer of the buffer layer is further doped with cadmium.

6. The photovoltaic device of claim 1, wherein the second layer of the buffer layer has a two-layer structure, including a zinc-containing layer comprising the zinc-containing compound, and a cadmium-containing layer comprising the cadmium-containing compound.

7. The photovoltaic device of claim 6, wherein the zinc-containing layer has a thickness in the range of from 1 nm to 60 nm, and the cadmium-containing layer has a thickness in the range of 1 nm to 100 nm.

8. The photovoltaic device of claim 1, wherein the second layer of the buffer layer has a single-layer structure and comprises the zinc-containing compound disposed over the first layer of the buffer layer, and the cadmium-containing compound impregnating the zinc-containing compound.

9. The photovoltaic device of claim 8, wherein the zinc-containing compound in the second layer of the buffer layer is in a shape of selected from a group consisting of irregular particles, tubes, and spherical particles.

10. A photovoltaic device comprising
a substrate;
a back contact layer disposed above the substrate;
an absorber layer comprising an absorber material disposed above the back contact layer; and
a buffer layer disposed above the absorber layer,
wherein the buffer layer includes a first layer comprising the absorber material doped with zinc, a second layer comprising a zinc-containing compound, and a third layer comprising a cadmium-containing compound.

11. The photovoltaic device of claim 10, wherein the first layer of the buffer layer comprises copper indium gallium selenide (GIGS) doped with zinc in the range of from 0.1 atomic % to 5 atomic %.

12. The photovoltaic device of claim 10, wherein the first layer of the buffer layer has the thickness in the range of from 5 nm to 20 nm.

13. The photovoltaic device of claim 10, wherein the second layer comprises at least one of zinc sulfide and zinc selenide, and has a thickness in the range of from 5 nm to 20 nm; and the third layer comprises cadmium sulfide and has a thickness in the range of from 5 nm to 60 nm.

14. A method of fabricating a photovoltaic device, comprising
forming a back contact layer above a substrate;
forming an absorber layer comprising an absorber material above the back contact layer;
forming a first layer of a buffer layer, the first layer comprising the absorber material doped with zinc; and
forming a second layer of the buffer layer above the first layer, the second layer comprising a zinc-containing compound and a cadmium-containing compound.

15. The method of claim 14, wherein the first layer of the buffer layer is formed through doping zinc into a top surface of the absorber layer.

16. The method of claim 14, wherein the step of forming the second layer of the buffer layer comprises
forming a zinc-containing layer comprising a zinc-containing compound; and
forming a cadmium-containing layer comprising a cadmium-containing compound.

17. The method of claim 16, wherein the step of forming the second layer of the buffer layer comprises:
depositing a zinc-containing compound over the first layer of the buffer layer, and forming a cadmium-containing compound impregnating or disposed over the zinc-containing compound,
wherein the zinc-containing compound in the second layer of the buffer layer is in a shape of selected from a group consisting of irregular particles, tubes, and spherical particles.

18. The method of claim 16, wherein the zinc-containing layer and the cadmium-containing layer are two distinct layers.

19. The method of claim 16, where the steps of forming the zinc-containing layer and the cadmium-containing layer include using a chemical bath deposition (CBD) method.

20. The method of claim 14, further comprising forming a transparent conductive layer over the buffer layer.
